(19) United States
(12) Patent Application Publication
(10) Pub. No.: US 2005/0077610 A1
(43) Pub. Date: Apr. 14, 2005

(54) Ball grid array package with external leads

(76) Inventors: Tzyy Haw Tan, Penang (MY); Suet Chieu Woon, Penang (MY); Say Toon Tan, Selangor (MY)

Correspondence Address: EITAN, PEARL, LATZER & COHEN ZEDEK LLP, 10 ROCKEFELLER PLAZA, SUITE 1001, NEW YORK, NY, 10020, US

(21) Appl. No.: 10/680,099

(22) Filed: Oct. 8, 2003

(51) Int. Cl. H01L 23/48

(52) U.S. Cl. 257/696

(57) ABSTRACT

In some embodiments, a package suitable to contain one or more semiconductor dies includes one or more solder-balls at an underside of said package and one or more external leads at a side edge of said package. Any or all of the solder-balls and external leads may serve as external electrical terminations of the package. The external leads may be surface mount leads and/or through-hole leads. In some embodiments, a printed circuit board may include pads designed to be soldered to solder-balls of a package and pads designed to be soldered to external leads of the package.

### BACKGROUND OF THE INVENTION

A package suitable to contain one or more semiconductor dies may comprise solder-balls in a ball grid array (BGA). Any or all of the solder-balls may serve as external electrical terminations of the package. A package with one or more semiconductor dies installed therein is known as a device.

During the reflow soldering process while the device is soldered onto a printed circuit board (PCB), non-coplanarity of the package being soldered on the PCB may result in solder ball damage. The non-coplanarity may be a result of an uneven thermal profile across the solder ball grid during the reflow soldering process.

Once a device is soldered onto a PCB, mechanical strains may occur between the package and the PCB. In packages comprising BGA solder-balls and not comprising external leads, such mechanical strains may result in damage to the soldered solder-balls over time.

### BRIEF DESCRIPTION OF THE DRAWINGS

Embodiments of the invention are illustrated by way of example and not limitation in the figures of the accompanying drawings, in which like reference numerals indicate corresponding, analogous or similar elements, and in which:

FIG. 1 is a top view of an exemplary package in accordance with some embodiments of the invention;

FIG. 2A is a cross-sectional view of the exemplary package of FIG. 1;

FIG. 2B is an alternative cross-sectional view of the exemplary package of FIG. 1;

FIG. 2C is an alternative cross-sectional view of the exemplary package of FIG. 1;

FIG. 3 is a top view of an exemplary printed circuit board in accordance with some embodiments of the invention;

FIG. 4 is a top view of an exemplary printed circuit board having devices installed thereon, in accordance with some embodiments of the invention; and

FIG. 5 is a top view of an exemplary apparatus including an exemplary printed circuit board, the exemplary printed circuit board having devices installed thereon, in accordance with some embodiments of the invention.

It will be appreciated that for simplicity and clarity of illustration, elements shown in the figures have not necessarily been drawn to scale. For example, the dimensions of some of the elements may be exaggerated relative to other elements for clarity.

### DETAILED DESCRIPTION OF EMBODIMENTS OF THE INVENTION

In the following detailed description, numerous specific details are set forth in order to provide a thorough understanding of embodiments of the invention. However it will be understood by those of ordinary skill in the art that the embodiments of the invention may be practiced without these specific details. In other instances, well-known methods, procedures, components and circuits have not been described in detail so as not to obscure the embodiments of the invention.

According to some embodiments of the invention, a package suitable to contain one or more semiconductor dies may comprise solder-balls in a ball grid array (BGA) and may comprise one or more external leads. Any or all of the solder-balls and external leads may serve as external electrical terminations of the package.

For example, the package may contain a substrate having patterns of metal conductors formed therein for internal signal traces. The substrate may comprise polyimide resin or a reinforced polymer laminate material such as bismaleimide triazine. The conductors may include wire bonding pads for connecting bond wires to the die and ball bonding pads for attaching external ball contacts such as solder balls. An encapsulating resin, such as, for example, a Novolac-based epoxy, may be molded onto the substrate to encapsulate the die and bond wires. The package may include a plastic package having a metal lead frame from which the leads are formed. The leads may be connected to the die on the inside of the package and extend to the outside of the package to form the external leads.

A package with one or more semiconductor dies installed therein is known as a device.

During the reflow soldering process in which the device is soldered onto a printed circuit board (PCB), the solder balls will melt and the device will sink due to its own weight. The presence of external leads on the side edges of the device may limit the package from sinking unevenly, thus helping to maintain the coplanarity of the device.

As is known in the art, once a device is soldered onto a printed circuit board (PCB), mechanical strains may occur between the package and the PCB. In packages comprising BGA solder-balls and not external leads, such mechanical strains may result in damage to the soldered solder-balls over time. In contrast, having one or more external leads in a package comprising solder-balls may result in protection, at least in part, for the soldered solder-balls from such mechanical strains. The materials from which the external leads are constructed and/or the mechanical size and shape and/or the placement and/or the number of the external leads may be chosen to provide protection, at least in part, for anticipated mechanical strains.

Since the external leads may be suitable to carry more current than a solder-ball, and since the external leads are located on the side edges of the package (enabling easy access thereto), one or more of the external leads may be electrically coupled to a power supply for the semiconductor die. Similarly, one or more of the external leads may be electrically coupled to a power return (ground) for the semiconductor die. Moreover, a single external lead may be able to replace several solder-balls for the function of carrying power supply or ground current. When power supply and ground are carried on external leads, this may facilitate improved testing of power supply and ground.

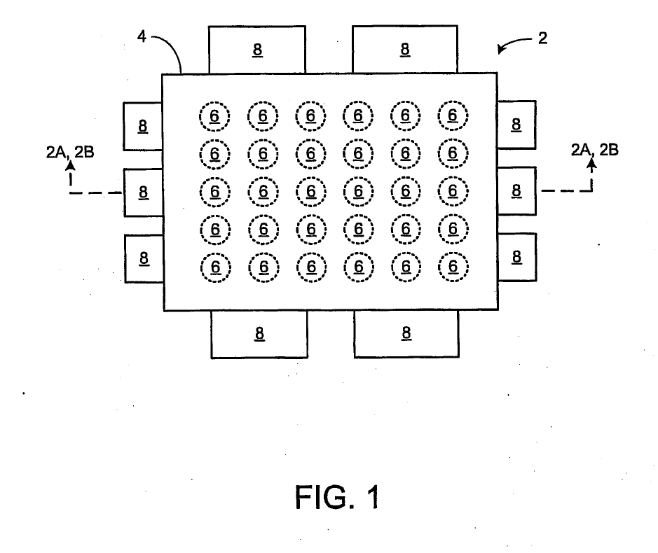

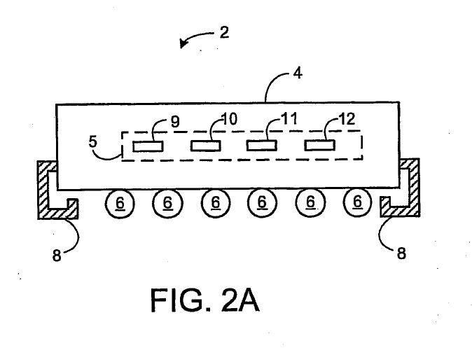

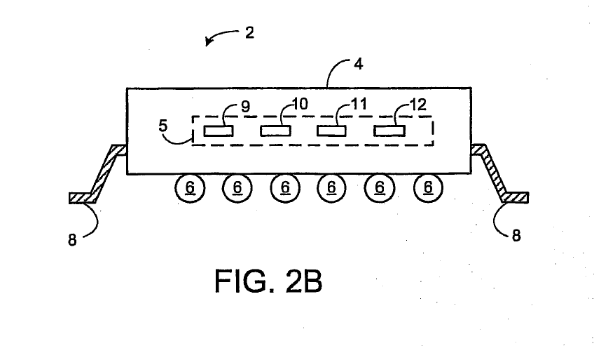

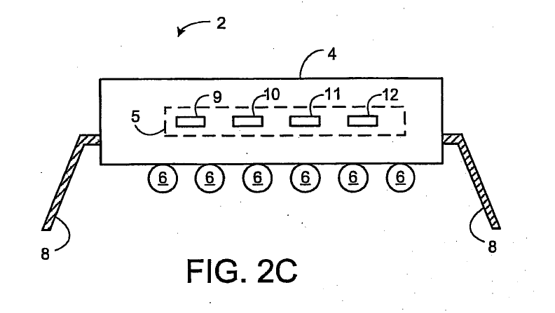

Referring to FIG. 1, FIG. 2A, FIG. 2B and FIG. 2C, an exemplary package 2 in accordance with an embodiment of the invention is illustrated. FIG. 1 is a top view of package 2, while FIG. 2A, FIG. 2B and FIG. 2C are alternative cross-sectional views of package 2.

Package 2 may be suitable to contain a semiconductor die 5, which is shown in FIGS. 2A, 2B and 2C. Therefore package 2 may comprise a body 4 of any appropriate shape to encase semiconductor die 5 once semiconductor die 5 is installed therein. Package 2 may also comprise solder-balls 6 and external leads 8. Package 2 may comprise additional components and mechanical features, which are not shown for clarity.

A non-exhaustive list of exemplary materials from which body 4 may be constructed includes resins, polymers, ceramic materials, metals and any combination thereof.

Solder-balls 6 are located on or partially embedded in a bottom surface of body 4. A non-exhaustive list of exemplary materials from which solder-balls 6 may be constructed includes tin-silver-copper (SnAgCu), tin-lead-silver (SnPbAg), eutectic solder, unleaded solder, or any other suitable soft soldering conducting material.

Although package 2 is shown as comprising thirty solder-balls 6 arranged in an array of six columns and five rows, this is an example only, and any number and any arrangement of solder-balls 6 located on or partially embedded in the bottom surface of body 4 is possible.

Although in package 2 solder-balls 6 are shown as having a spherical shape, this is an example only, and any shape is possible. Moreover, the shape of solder-balls 6 may change during the soldering of package 2 to a PCB.

Any number of external leads 8 of any shape and any size may be located anywhere along the side edges of body 4. The shapes, sizes and types of external leads 8 may be identical or may not be identical. For example, the external leads may be surface mount leads and/or through-hole leads. A non-exhaustive list of exemplary materials from which external leads 8 may be constructed includes nickel-plated copper, silver-plated materials, nickel-plated gold or any other suitable hard metallic conducting material.

As shown in FIG. 1, exemplary package 2 comprises ten surface mount and/or through-hole leads 8. As an example, FIG. 2A shows “J-lead” type surface mount leads, while FIG. 2B shows “Gull-Wing” type surface mount leads and FIG. 2C shows through-hole leads. All the leads of a package may be of the same type, or may be of different types.

Semiconductor die 5 may comprise circuitry 9 and pads 10, 11, and 12. Semiconductor die 5 may comprise additional pads that are not shown for clarity.

A non-exhaustive list of exemplary functionality that circuitry 9 implements includes a processor, a graphical processor, a peripheral component interconnect (PCI) north bridge, a PCI south bridge, a communication processor, a memory controller, a wireless local area network (LAN) controller, a radio frequency (RF) controller, a video processor and the like.

As an example, pad 10 may be a power supply terminal of circuitry 9, pad 11 may be a power return (“ground”) terminal of circuitry 9, and pad 12 may carry a signal to and/or from circuitry 9.

Once semiconductor die 5 is installed in package 2, pads 10, 11 and 12 may each be electrically coupled to a respective one of the external leads 8, whereas one or more of the other external leads 8 may not be electrically coupled to any of the pads of semiconductor die 5.

A non-exhaustive list of the devices device formed by semiconductor die 5 and package 2 includes a field programmable gate array (FPGA), an application specific integrated circuit (ASIC), a reduced instruction set computer (RISC), a complex instruction set computer (CISC), an application specific standard product (AS SP) and the like.

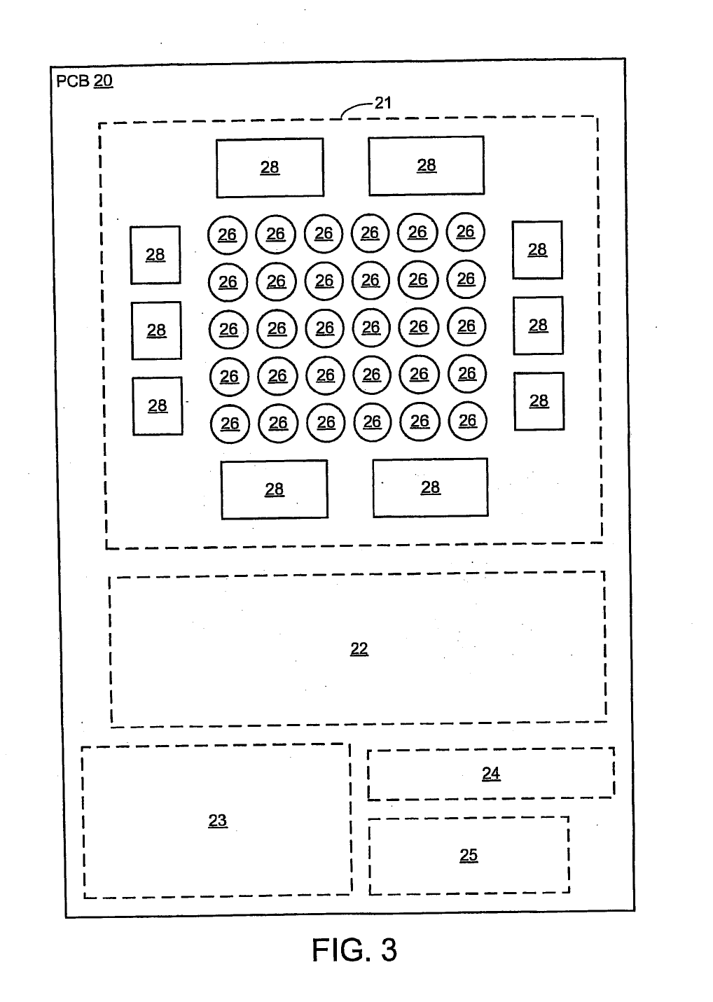

FIG. 3 shows an exemplary PCB 20 in accordance with some embodiments of the invention. PCB 20 may comprise, for example, “footprints” 21, 22, 23, 24, and 25 for respective devices. Mechanical features and additional footprints of PCB 20 are not shown for clarity. Footprint 21 may be suitable to have installed thereon a device whose package is similar or the same as package 2 shown in FIG. 1. Footprint 21 may comprise pads 26 suitable to be soldered to respective solder-balls 6 of package 2, and pads 28 may be suitable to be soldered to respective external leads 8 of package 2. If a particular pad 28 is suitable to be soldered to a through-hole lead, then there is a hole (not shown) in that particular pad. PCB 20 may comprise physical traces (not shown) for any or all of the pads of the footprints.

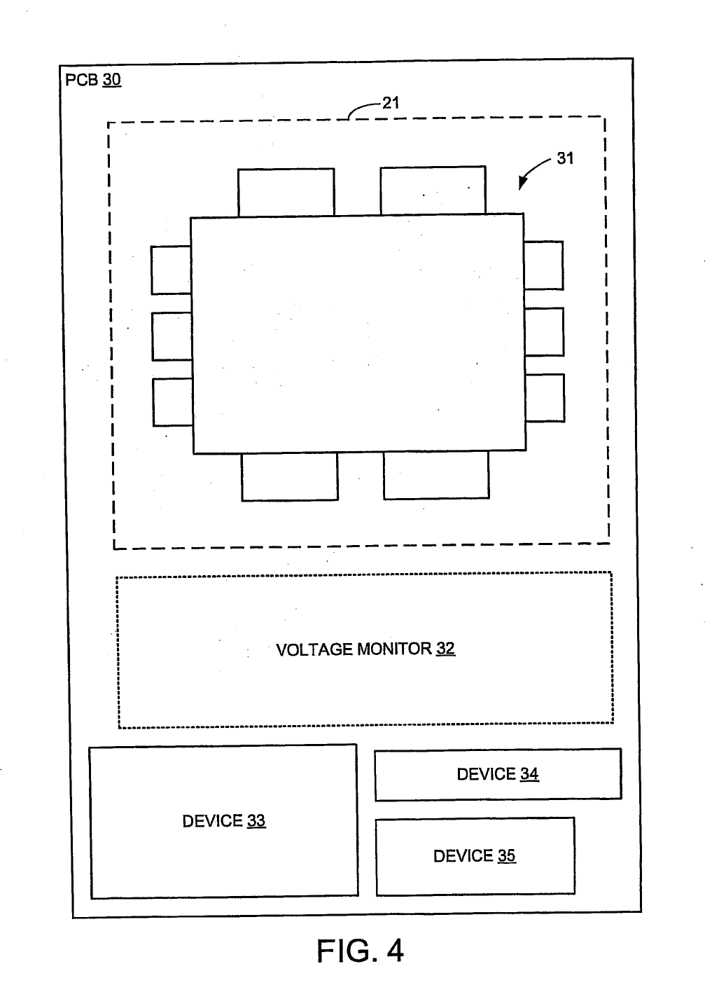

FIG. 4 shows an exemplary PCB 30 in accordance with some embodiments of the invention. PCB 30 may have installed thereon some devices, for example, devices 33, 34, and 35, and may optionally have installed thereon a voltage monitor 32. PCB 30 may have installed on footprint 21 a device 31 comprising a package containing one or more semiconductor dies, where the package is similar or the same as package 2 shown in FIG. 1. Mechanical features and additional footprints of PCB and additional devices installed on PCB 30 are not shown for clarity.

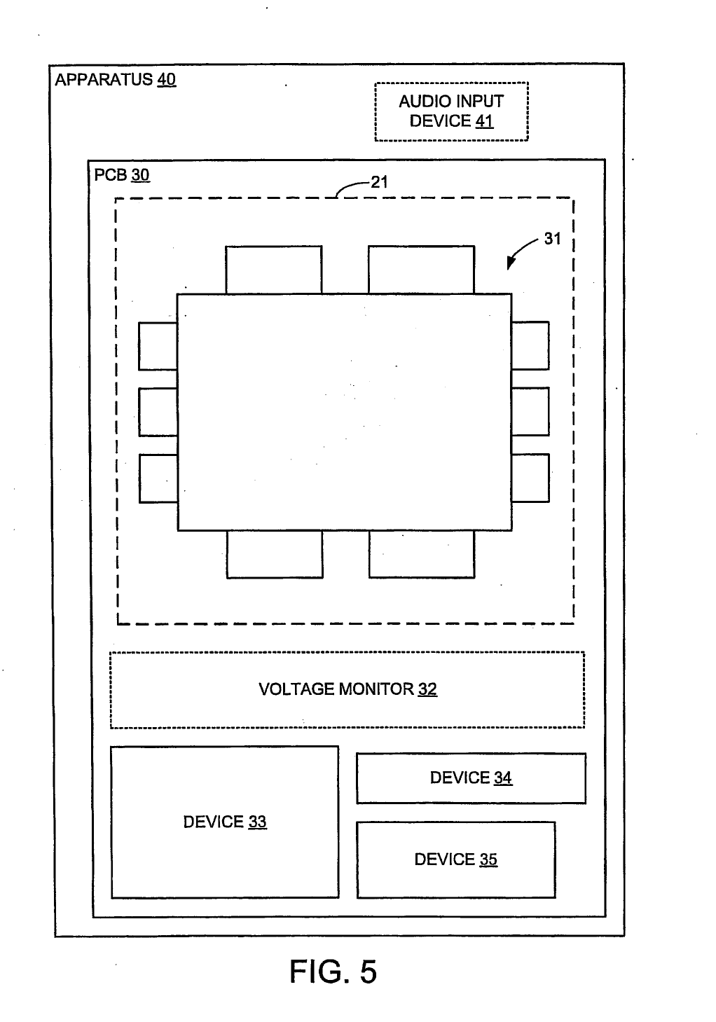

FIG. 5 shows an exemplary apparatus 40 in accordance to some embodiments of the invention. Apparatus 40 may comprise PCB 30 of FIG. 5, and may optionally comprise an audio input device 41. A non-exhaustive list of examples for apparatus 40 includes a personal computer (PC), a notepad computer, a notebook computer, a laptop computer, a server computer, a pocket PC, a personal digital assistant (PDA), a personal information manager (PIM), a cellphone, a pager, a mobile or non-mobile memory storage device, a hard disk drive (HDD), a floppy disk drive (FDD), a monitor, a projector, a digital video disc (DVD) player, a video compact disc (VCD) player, an MP3 player, a mobile media player, a calculator, and the like.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

1. A package suitable to contain a semiconductor die, the package comprising:
at least one solder-ball at an underside of said package; and
at least one external lead at a side edge of said package.

2. The package of claim 1, wherein said external lead is a surface mount lead of type J-lead.

3. The package of claim 1, wherein said external lead is a surface mount lead of type Gull-wing.

4. The package of claim 1, wherein said external lead is a through-hole lead.

5. The package of claim 1, wherein once said external lead is soldered to a printed circuit board, said external lead is to absorb part of a strain between said package and said printed circuit board, wherein said strain is one of the following: a thermal strain, a mechanical strain, and a thermomechanical strain.

6. A device comprising:
a semiconductor die; and
a package containing said semiconductor die, said package including at least:
at least one solder-ball at an underside of said package; and
at least one external lead at a side edge of said package.

7. The device of claim 6, wherein said external lead is electrically coupled to one or more pads of said semiconductor die.

8. The device of claim 7, wherein said one or more pads are ground terminals of circuitry in said semiconductor die.

9. The device of claim 7, wherein said one or more pads are power supply terminals of circuitry in said semiconductor die.

10. The device of claim 7, wherein said one or more pads are to carry signals of circuitry in said semiconductor die.

11. The device of claim 7, wherein said external lead is a surface mount lead of type J-lead.

12. The device of claim 7, wherein said external lead is a surface mount lead of type Gull-wing.

13. The device of claim 7, wherein said external lead is a through-hole lead.

14. A printed circuit board comprising:
pads suitable to be soldered to solder-balls of a package; and
pads suitable to be soldered to external leads of said package.

15. The printed circuit board of claim 14, wherein at least one of said external leads is a surface mount lead of type J-lead.

16. The printed circuit board of claim 14, wherein at least one of said external leads is a surface mount lead of type Gull-wing.

17. The printed circuit board of claim 14, wherein at least one of said pads has a hole therein.

18. A printed circuit board having a device installed thereon, the printed circuit board comprising:
pads soldered to solder-balls of a package of said device; and
pads soldered to external leads of said package, wherein said printed circuit board has a voltage monitor installed thereon.

19. The printed circuit board of claim 18, wherein at least one of said external leads is a surface mount lead of type J-lead.

20. The printed circuit board of claim 18, wherein at least one of said external leads is a surface mount lead of type Gull-wing.

21. The printed circuit board of claim 18, wherein at least one of said pads has a hole therein.

22. The printed circuit board of claim 18, wherein said printed circuit board is a motherboard.

23. An apparatus comprising:
an audio input device; and
a printed circuit board having a device installed thereon, said printed circuit board including at least:
pads soldered to solder-balls of a package of said device; and
pads soldered to external leads of said package.

24. The apparatus of claim 23, wherein at least one of said external leads is a surface mount lead of type J-lead.

25. The apparatus of claim 23, wherein at least one of said external leads is a surface mount lead of type Gull-wing.

26. The apparatus of claim 23, wherein at least one of said pads has a hole therein.

27. The apparatus of claim 23, wherein said apparatus is a computer.
